(19) United States
(12) Patent Application Publication
(10) Pub. No.: US 2024/0120370 A1
(43) Pub. Date: Apr. 11, 2024

(54) VERTICALLY CONDUCTIVE SEMICONDUCTOR STRUCTURES AND MANUFACTURING METHODS THEREFOR

(71) Applicant: ENKRIS SEMICONDUCTOR, INC., Suzhou (CN)

(72) Inventor: Kai Cheng, Suzhou (CN)

(73) Assignee: ENKRIS SEMICONDUCTOR, INC., Suzhou (CN)

(21) Appl. No.: 18/473,878

(22) Filed: Sep. 25, 2023

(30) Foreign Application Priority Data
Oct. 8, 2022 (CN) 202211223425X

(51) Int. Cl. H01L 29/06; H01L 21/265; H01L 29/08

(52) U.S. Cl. CPC H01L 29/0607; H01L 21/26513; H01L 29/0847

(57) ABSTRACT

The present disclosure provides a vertically conductive semiconductor structure, including a heavily doped layer, a first semiconductor layer, a second semiconductor layer and an ion implanted region in the second semiconductor layer. Conductivity types of the heavily doped layer and the first semiconductor layer are same, and conductivity types of the first semiconductor layer and the second semiconductor layer are opposite. Materials of the first semiconductor layer and the second semiconductor layer are GaN-based materials. Conductivity types of the ion implanted region and the second semiconductor layer are opposite. The ion implanted region includes a first end and a second end that are opposite to each other. The first end is flush with a surface of the second semiconductor layer far from the first semiconductor layer, and the second end connects the first semiconductor layer. A width of the ion implanted region from bottom to top varies.

### CROSS REFERENCE TO RELATED APPLICATIONS

This application claims priority to Chinese Patent Application No. 202211223425X filed on Oct. 8, 2022, the entire content of which is incorporated herein by reference.

### TECHNICAL FIELD

The present disclosure relates to the technical field of semiconductor, in particular to vertically conductive semiconductor structures and manufacturing methods therefor.

### BACKGROUND

Gallium nitride (GaN), as a representative of the third generation of wide band gap semiconductor, is attracting widespread attention. Properties of GaN mainly include high electron mobility and high two-dimensional electron gas (2DEG) concentration. In addition, GaN material has stable chemical properties, high temperature resistance and corrosion resistance, and has inherent advantages in high-frequency, high-power, and radiation-resistant applications.

In a horizontal GAN-based high electron mobility transistor (HEMT) device, in order to obtain higher breakdown voltage, it is necessary to increase a gate-to-drain space, which will increase a size and a conduction resistance of the device, reduce an effective current density per unit chip area and a chip performance, and thus lead to an increase in chip area and development costs. To address the above problems, researchers have proposed a GAN-based vertically conductive semiconductor structure.

### SUMMARY

The first aspect of the present disclosure provides a vertically conductive semiconductor structure, including:

a heavily doped layer, a first semiconductor layer, and a second semiconductor layer that are arranged from bottom to top, where conductivity types of the heavily doped layer and the first semiconductor layer are same, and conductivity types of the first semiconductor layer and the second semiconductor layer are opposite, and materials of the first semiconductor layer and the second semiconductor layer are GaN-based materials; and

an ion implanted region in the second semiconductor layer, where conductivity types of the ion implanted region and the second semiconductor layer are opposite, the ion implanted region includes a first end and a second end that are opposite to each other in a thickness direction, where the first end is flush with a surface of the second semiconductor layer far from the first semiconductor layer, and the second end connects the first semiconductor layer, and a width of the ion implanted region from bottom to top varies.

In some embodiments, from bottom to top, the width of the ion implanted region periodically varies, gradually increases, gradually decreases, first increases and then decreases, or first decreases and then increases.

In some embodiments, the vertically conductive semiconductor structure further includes a passivated layer on the surface of the second semiconductor layer far from the first semiconductor layer, where a material of the passivated layer is AlGaN, and a content of Al in the AlGaN increases from bottom to top in the thickness direction of the passivated layer.

In some embodiments, from bottom to top, a concentration of doped ions in the ion implanted region at least one of: is unchanged, periodically varies, gradually increases, or gradually decreases.

In some embodiments, a conductivity type of the first semiconductor layer is N-type, and a conductivity type of the second semiconductor layer is P-type; or a conductivity type of the first semiconductor layer is P-type, and a conductivity type of the second semiconductor layer is N-type.

In some embodiments, the vertically conductive semiconductor structure further includes:

a source electrode connecting the first end of the ion implanted region;

a gate electrode at both sides of the source electrode, where the gate electrode connects the second semiconductor layer at both sides of the ion implanted region; and

a drain electrode connecting a surface of the heavily doped layer far from the first semiconductor layer.

In some embodiments, the vertically conductive semiconductor structure further includes:

a first electrode connecting the second semiconductor layer adjacent to the ion implanted region and the ion implanted region; and

a second electrode connecting the heavily doped layer.

In some embodiments, the ion implanted region further includes a heavily doped region far from the first semiconductor layer, where conductivity types of the heavily doped region and the second semiconductor layer are opposite.

In some embodiments, the vertically conductive semiconductor structure further includes: a buffer layer between the heavily doped layer and the first semiconductor layer.

In some embodiments, the first semiconductor layer includes a first surface facing away from the heavily doped layer, where the first surface is provided with a plurality of first protrusions, and the ion implanted region is above each of the plurality of the first protrusions; and a surface of the second semiconductor layer facing away from the first semiconductor layer is provided with a plurality of second protrusions corresponding to the plurality of the first protrusions, or a surface of the second semiconductor layer facing away from the first semiconductor layer is flat.

In some embodiments, the second semiconductor layer includes a first doped layer and a second doped layer that are stacked, where the first doped layer is close to the first semiconductor layer, and the second doped layer is far from the first semiconductor layer, and a conductive-ion doping concentration of the first doped layer is lower than a conductive-ion doping concentration of the second doped layer.

The second aspect of the present disclosure provides a method for manufacturing a vertically conductive semiconductor structure, including:

providing a heavily doped layer, a first semiconductor layer, and a second semiconductor layer that are arranged from bottom to top, where conductivity types of the heavily doped layer and the first semiconductor layer are same, and conductivity types of the first semiconductor layer and the second semiconductor layer are opposite, and materials of the first semiconductor layer and the second semiconductor layer are GaN-based materials; and

implanting ions in a region of a part of the second semiconductor layer to form an ion implanted region, where conductivity types of the ion implanted region and the second semiconductor layer are opposite, the ion implanted region connects the first semiconductor layer, and a width of the ion implanted region from bottom to top varies.

In some embodiments, before implanting the ions in the region of the part of the second semiconductor layer, the method further includes: forming an in-situ protecting layer on a surface of the second semiconductor layer far from the first semiconductor layer; and

after implanting the ions in the region of the part of the second semiconductor layer, the method further includes: performing first annealing, where a temperature of the first annealing is greater than 1100° C.; and removing the in-situ protecting layer and performing second annealing, where a temperature of the second annealing is less than 700° C.

In some embodiments, the in-situ protecting layer is a single-layer structure, and a material of the single-layer structure includes a mixture of at least one of SiN or AlN; or the in-situ protecting layer (20) is a multi-layer structure, and the multi-layer structure from bottom to top includes an SiN layer and an AlN layer, an AlN layer and an SiN layer, or an SiN layer, an AlN layer and an SiN layer.

In some embodiments, the conductivity type of the second semiconductor layer is P-type, and H ions and at least one of Si ions, Ge ions, Sn ions, Se ions or Te ions are doped to form the ion implanted region with N-type conductivity.

In some embodiments, the ion implanted region with varying widths and/or varying doping ion concentrations is obtained through multiple ion implantations.

In some embodiments, from bottom to top, the width of the ion implanted region periodically varies, gradually increases, gradually decreases, first increases and then decreases, or first decreases and then increases.

In some embodiments, from bottom to top, a concentration of doped ions in the ion implanted region at least one of: is unchanged, periodically varies, gradually increases, or gradually decreases.

In some embodiments, the multiple ion implantations include vertical implantation and oblique implantation.

In some embodiments, in the multiple ion implantations, energies of at least two ion implantations are different and/or amounts of at least two ion implantations are different.

In some embodiments, the method for manufacturing a vertically conductive semiconductor structure further includes:

forming a source electrode, a gate electrode, and a drain electrode respectively, where the source electrode connects the first end of the ion implanted region; the gate electrode is located at both sides of the source electrode, where the gate electrode connects the second semiconductor layer at both sides of the ion implanted region; and the drain electrode connects a surface of the heavily doped layer far from the first semiconductor layer.

In some embodiments, the method for manufacturing a vertically conductive semiconductor structure further includes:

forming a first electrode and a second electrode respectively, where the first electrode connects the second semiconductor layer adjacent to the ion implanted region and the ion implanted region; and the second electrode connects the heavily doped layer.

In some embodiments, the method for manufacturing a vertically conductive semiconductor structure further includes: implanting ions in a region of the ion implanted region far from the first semiconductor layer to form a heavily doped region, where conductivity types of the heavily doped region and the second semiconductor layer are opposite.

In some embodiments, the first semiconductor layer and the second semiconductor layer are sequentially formed by performing epitaxial growth processes on a substrate, where the first semiconductor layer includes a first surface facing away from the heavily doped layer, and the first surface is formed with a plurality of first protrusions; in the epitaxial growth processes, the ion implanted region is formed above the first protrusion; and a surface of the second semiconductor layer facing away from the first semiconductor layer is formed with a plurality of second protrusions corresponding to the plurality of the first protrusions, or a surface of the second semiconductor layer facing away from the first semiconductor layer is flat.

In some embodiments, the substrate is a patterned substrate serving as a template and includes a patterned structure corresponding to the plurality of the first protrusions; or the substrate is a planar substrate, and the heavily doped layer serves as a template and includes a patterned structure corresponding to the plurality of the first protrusions.

In some embodiments, after implanting the ions in the region of the part of the second semiconductor layer to form the ion implanted region, the method further includes: forming a passivated layer on surfaces of the ion implanted region and the second semiconductor layer that are facing away from the first semiconductor layer, where a material of the passivated layer is AlGaN, and a content of Al in the AlGaN increases from bottom to top in the thickness direction of the passivated layer.

### BRIEF DESCRIPTION OF DRAWINGS

FIG. 1 is a cross-sectional diagram of a vertically conductive semiconductor structure according to the first embodiment of the present disclosure.

FIG. 2 is a flowchart of a method for manufacturing the vertically conductive semiconductor structure in FIG. 1.

FIG. 3 is a schematic diagram of an intermediate structure corresponding to a process in FIG. 2.

FIG. 4 is a cross-sectional diagram of a vertically conductive semiconductor structure according to the second embodiment of the present disclosure.

FIG. 5 is a cross-sectional diagram of a vertically conductive semiconductor structure according to the third embodiment of the present disclosure.

FIG. 6 is a cross-sectional diagram of a vertically conductive semiconductor structure according to the fourth embodiment of the present disclosure.

FIG. 7 is a cross-sectional diagram of a vertically conductive semiconductor structure according to the fifth embodiment of the present disclosure.

FIG. 8 is a cross-sectional diagram of a vertically conductive semiconductor structure according to the sixth embodiment of the present disclosure.

FIG. 9 is a schematic diagram of an intermediate structure corresponding to a method for manufacturing the vertically conductive semiconductor structure in the sixth embodiment of the present disclosure.

FIG. 10 is a cross-sectional diagram of a vertically conductive semiconductor structure according to the seventh embodiment of the present disclosure.

For the convenience of understanding the present disclosure, all reference numerals appearing in the present disclosure are listed below.

| vertically conductive semiconductor structures 1, 2, 3, 4, 5, 6, 7 | |
|---|---|
| substrate 10 | |
| heavily doped layer 11 | first semiconductor layer 12 |
| first surface 12a | first protrusion 121 |
| second semiconductor layer 13 | second protrusion 131 |
| first doped layer 132 | second doped layer 133 |
| ion implanted region 14 | first end 14a |
| second end 14b | heavily doped region 141 |
| source electrode 15 | gate electrode 16 |
| drain electrode 17 | passivated layer 18 |
| first section 181 | second section 182 |
| In-situ protecting layer 20 | mask layer 201 |
| first electrode 21 | second electrode 22 |

### DETAILED DESCRIPTION

In order to make the above-mentioned objects, features and advantages of the present disclosure more obvious and understandable, embodiments of the present disclosure will be described in detail below with reference to the accompanying drawings.

After years of research, an existing GAN-based vertically conductive semiconductor structure still has high conduction resistance, low breakdown voltage, and insufficient power to meet some application requirements.

In view of this, vertically conductive semiconductor structures and manufacturing methods therefor are provided in embodiments of the present disclosure, which reduces the conduction resistance, increases the breakdown voltage, and increases the power.

FIG. 1 is a cross-sectional diagram of a vertically conductive semiconductor structure according to the first embodiment of the present disclosure.

As shown in FIG. 1, the vertically conductive semiconductor structure 1 includes:

a heavily doped layer 11, a first semiconductor layer 12, and a second semiconductor layer 13 that are arranged from bottom to top, where conductivity types of the heavily doped layer 11 and the first semiconductor layer 12 are same, and conductivity types of the first semiconductor layer 12 and the second semiconductor layer 13 are opposite, and materials of the first semiconductor layer 12 and the second semiconductor layer 13 are GaN-based materials;

an ion implanted region 14 in the second semiconductor layer 13, where conductivity types of the ion implanted region 14 and the second semiconductor layer 13 are opposite, the ion implanted region 14 includes a first end 14a and a second end 14b that are opposite to each other in a thickness direction, where the first end 14a is flush with a surface of the second semiconductor layer 13 far from the first semiconductor layer 12, and the second end 14b connects the first semiconductor layer 12, and a width of the ion implanted region 14 from bottom to top varies;

a source electrode 15, connecting the first end 14a of the ion implanted region 14;

a gate electrode 16 at both sides of the source electrode 15, where the gate electrode 16 connects the second semiconductor layer 13 at both sides of the ion implanted region 14; and

a drain electrode 17, connecting a surface of the heavily doped layer 11 far from the first semiconductor layer 12.

In this embodiment, the vertically conductive semiconductor structure 1 is a junction field-effect transistor (JFET).

Materials of the heavily doped layer 11, the first semiconductor layer 12, and the second semiconductor layer 13 can include GAN-based materials, such as GaN.

In this embodiment, conductivity types of the heavily doped layer 11 and the first semiconductor layer 12 are N-type, where N-type doping ions can be at least one of Si ions, Ge ions, Sn ions, Se ions or Te ions. The conductivity type of the second semiconductor layer 13 is P-type, and P-type doping ions can be at least one of Mg ions, Zn ions, Ca ions, Sr ions or Ba ions. In other words, the junction field-effect transistor (JFET) is an N-type channel. In other embodiments, the conductivity types of the heavily doped layer 11 and the first semiconductor layer 12 can be P-type, while the conductivity type of the second semiconductor layer 13 can be N-type. In other words, the junction field-effect transistor (JFET) is a P-type channel.

Materials of the source electrode 15, the gate electrode 16 and the drain electrode 17 may be metals, such as Ti/Al/Ni/Au, Ni/Au, etc. A Schottky contact can be formed between the gate electrode 16 and the second semiconductor layer 13, and ohmic contacts can be formed between the source electrode 15 and the ion implanted region 14, and between the drain electrode 17 and the heavily doped layer 11.

In this embodiment, as shown in FIG. 1, from bottom to top, the width of the ion implanted region first increases and then decreases. In some embodiments, from bottom to top, the width of the ion implanted region 14 periodically varies, gradually increases, gradually decreases, or first decreases and then increases.

The junction field-effect transistor includes two PN junctions formed by the ion implanted region 14 and the second semiconductor layer 13 on both sides. By applying a voltage between the gate electrode 16 and the source electrode 15, the PN junction is reversed and a depletion layer at the interface of the PN junction becomes wider. When the channel is completely depleted, the junction field-effect transistor is in a pinched-off channel state, and the junction field-effect transistor is cut off. On the contrary, the junction field-effect transistor conducts.

Since the width of the ion implanted region periodically varies, gradually increases gradually decreases, first increases and then decreases, or first decreases and then increases, a contact interface between the ion implanted region 14 and a side of the second semiconductor layer 13 has periodic changes or forms a tilted surface. On the one hand, by controlling a shape of a PN junction contact interface, a reverse breakdown voltage can be effectively increased. On the other hand, during on state, due to the periodically changed curved surface, tilted surface, or curved surface of the contact interface, electrons flowing from the source electrode 15 to the drain electrode 17 can disperse to both sides and flow downwards, which increases the electron movement path, thus further reducing the on-state resistance of the junction field-effect transistor.

In addition, in the embodiments, by controlling the variation of the doped-ion concentration in the ion implanted region 14, the carrier concentration in the first semiconductor layer 12 can be locally modulated. For example, a concentration of doped ions in the ion implanted region 14 at least one of: is unchanged, periodically varies, gradually increases, or gradually decreases.

The effect of local modulation for the doped-ions in the ion implanted region 14 is to effectively reduce the peak electric field intensity near the PN junction interface during off state, thereby maximizing the breakdown voltage of the junction field-effect transistor. During on state, this structure has a characteristic of reducing the conduction resistance, which allows the junction field-effect transistor to have a lower voltage drop under high current density when turned on, thus, improving the energy conversion efficiency of the system using the junction field-effect transistor.

In some embodiments, the vertically conductive semiconductor structure 1 can omit the source electrode 15, gate electrode 16, and drain electrode 17, and be produced and sold as a semi-finished product.

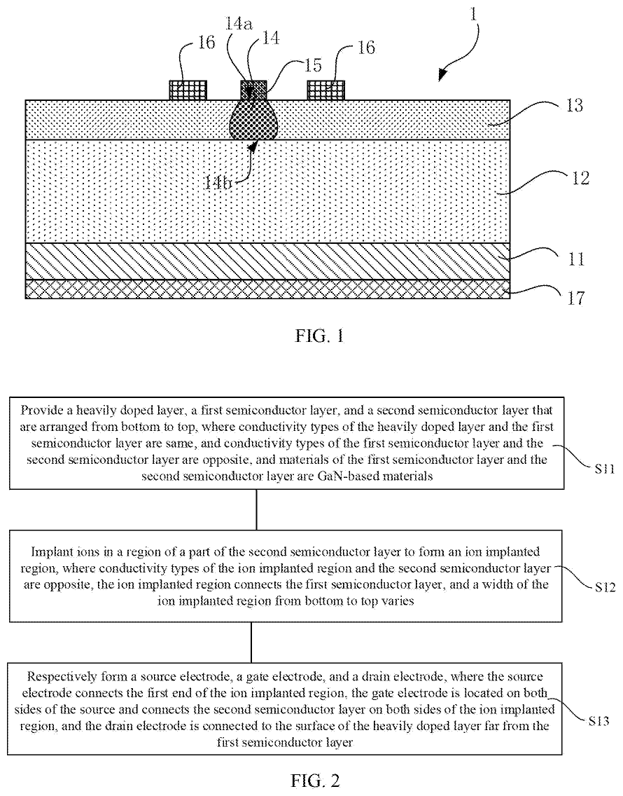

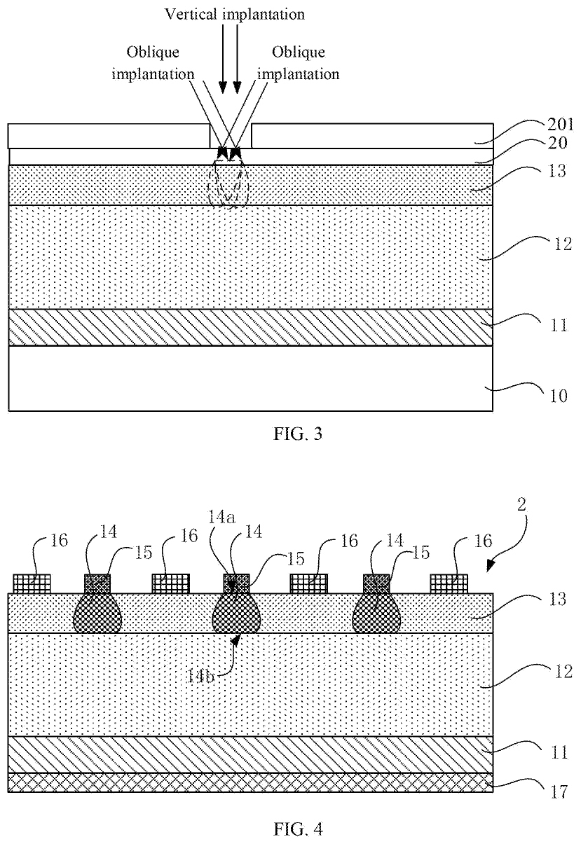

The first embodiment of the present disclosure further provides a method for manufacturing the vertically conductive semiconductor structure shown in FIG. 1. FIG. 2 is a flowchart of a method for manufacturing the vertically conductive semiconductor structure in FIG. 1. FIG. 3 is a schematic diagram of an intermediate structure corresponding to a process in FIG. 2.

Referring to step S11 in FIG. 2 and FIG. 3, a heavily doped layer 11, a first semiconductor layer 12, and a second semiconductor layer 13 that are arranged from bottom to top are provided, where conductivity types of the heavily doped layer 11 and the first semiconductor layer 12 are same, and conductivity types of the first semiconductor layer 12 and the second semiconductor layer 13 are opposite, and materials of the first semiconductor layer 12 and the second semiconductor layer 13 are GaN-based materials.

The heavily doped layer 11, first semiconductor layer 12, and second semiconductor layer 13 can be sequentially formed on a substrate 10 by epitaxial growth processes such as MBE (Molecular Beam Epitaxy) or MOCVD (Metal Organic Chemical Vapor Deposition). A material of substrate 10 can be sapphire, silicon carbide, silicon, or diamond. Materials of the heavily doped layer 11, the first semiconductor layer 12, and the second semiconductor layer 13 can include GAN-based materials, such as GaN. Conductivity types of the heavily doped layer 11 and the first semiconductor layer 12 can be N-type, where N-type doping ions can be at least one of Si ions, Ge ions, Sn ions, Se ions or Te ions. The conductivity type of the second semiconductor layer 13 is P-type, and P-type doping ions can be at least one of Mg ions, Zn ions, Ca ions, Sr ions or Ba ions. N-type doping ions and P-type doping ions can be doped through in-situ growth process.

Next, referring to steps S12 in FIG. 2 and FIG. 3, ions are implanted in a region of a part of the second semiconductor layer 13 to form an ion implanted region 14, where conductivity types of the ion implanted region 14 and the second semiconductor layer 13 are opposite, the ion implanted region 14 connects the first semiconductor layer 12, and a width of the ion implanted region 14 from bottom to top varies.

In this embodiment, the ion implanted region 14 formed by implanting ions includes a first end 14a and a second end 14b that are opposite to each other in a thickness direction, where the first end 14a is flush with a surface of the second semiconductor layer 13 far from the first semiconductor layer 12, and the second end 14b connects the first semiconductor layer 12.

In this embodiment, as shown in FIG. 1, from bottom to top, the width of the ion implanted region first increases and then decreases. In some embodiments, from bottom to top, the width of the ion implanted region 14 periodically varies, gradually increases, gradually decreases, or first decreases and then increases.

The ion implanted region 14 with widths varying from bottom to top can be obtained by multiple ion implantations, followed by high temperature annealing and thermal diffusion.

The multiple ion implantations include oblique ion implantation and vertical ion implantation.

The oblique ion implantation means that an angle between an ion implantation direction and a plane where the second semiconductor layer 13 is located is an acute angle. In some embodiments, the acute angle is greater than 45 degrees. The vertical ion implantation means that an angle between an ion implantation direction and a plane where the second semiconductor layer 13 is located is a right angle.

In the embodiment, ion implanted regions 14 with varying doping ion concentrations can also be obtained through multiple ion implantations. From bottom to top, a concentration of doped ions in the ion implanted region 14 at least one of: is unchanged, periodically varies, gradually increases, or gradually decreases.

In the multiple ion implantations, energies of at least two ion implantations are different and/or amounts of at least two ion implantations can be different.

As shown in FIG. 3, before the ions are implanted in the region of the part of the second semiconductor layer, an in-situ protecting layer 20 can be formed on a surface of the second semiconductor layer 13 far from the first semiconductor layer 12, and then ions are implanted in the region of a part of the second semiconductor layer 13 to form the ion implanted region 14. The conductivity type of the second semiconductor layer 13 is P-type, and after implantation with at least one of N-type doping ions such as Si ions, Ge ions, Sn ions, Se ions, or Te ions, the ion implanted region 14 with N-type conductivity is formed in the second semiconductor layer 13. It should be noted that N-type doping ions can co doped with H ions to form the ion implanted region 14 with N-type conductivity. H ions passivate the P-type second semiconductor layer 13, and N-type doping ions are used to form an N-type ion implanted region 14 in a region of a part of the passivated second semiconductor layer 13. Adding H ions for co doping can further improve ion implantation efficiency.

The in-situ protecting layer 20 can be a single-layer structure, and a material of the single-layer structure can include a mixture of one or more of SiN or AlN. Alternatively, the in-situ protecting layer 20 is a multi-layer structure. From bottom to top, the multi-layer structure can include: SiN layer and AlN layer, AlN layer and SiN layer, or SiN layer, AlN layer and SiN layer.

After the ions are implanted in the region of a part of the second semiconductor layer, under the protection of the nitride in-situ protecting layer 20, the first annealing is carried out to activate the N-type doped ions in the ion implanted region 14. A temperature of the first annealing is greater than 1100° C.

Afterwards, the in-situ protecting layer 20 is removed and second annealing is carried out to release the H ions in the passivated second semiconductor layer 13, to activate the P-type doped ions in the second semiconductor layer 13. A temperature of the second annealing is less than 700° C.

When N-type ions, such as Si ions, are doped in the ion implanted region 14, high-temperature annealing is required to transform the ion implanted region 14 from P-type doped to N-type doped. However, high-temperature annealing can cause surface defects in the ion implanted region 14 or the second semiconductor layer 13. The in-situ protecting layer 20 can avoid these defects, and the nitride in-situ protecting layer 20 is used to repair defects in the ion implanted region 14 and the second semiconductor layer 13 during the high-temperature annealing.

As shown in FIG. 3, before the ions are implanted in the region of a part of the second semiconductor layer, a patterned mask layer 201 can be formed on the second semiconductor layer 13. A material of the patterned mask layer 201 is, for example, silicon nitride or silicon dioxide. The patterned mask layer 201 has an opening for exposing a region for the ion implanted region 14 to be formed. After the ions are implanted in the region of a part of the second semiconductor layer, the patterned mask layer 201 can be removed.

The ion implanted region 14 is formed by ion implantation, which can, compared to a manufacturing process of filling semiconductor materials after etching grooves, reduce defects, avoid capture of carriers in the channel during conduction, increase conduction current, and thereby increase power and reduce conduction resistance.

Afterwards, referring to step S13 in FIG. 2 and FIG. 1, a source electrode 15, a gate electrode 16, and a drain electrode 17 are respectively formed. The source electrode 15 connects the first end 14a of the ion implanted region 14. The gate electrode 16 is located on both sides of the source 15, and connects the second semiconductor layer 13 on both sides of the ion implanted region 14. The drain electrode 17 is connected to the surface of the heavily doped layer 11 far from the first semiconductor layer 12.

Before the drain electrode 17 is formed, the substrate 10 can be removed. The substrate 10 can be removed by laser peeling-off.

Materials of source electrode 15, gate electrode 16 and drain electrode 17 can be metals, such as Ti/Al/Ni/Au, Ni/Au, etc., and can be formed by physical vapor deposition or chemical vapor deposition.

FIG. 4 is a cross-sectional diagram of a vertically conductive semiconductor structure according to the second embodiment of the present disclosure.

As shown in FIG. 4, a difference between a vertically conductive semiconductor structure 2 and a manufacturing method therefor according to the second embodiment and the vertically conductive semiconductor structure 1 and manufacturing method therefor according to the first embodiment is only that there are two or more ion implanted regions 14, and source electrodes 15 corresponding to the ion implanted regions 14 can be connected together, and gate electrodes 16 corresponding to the second semiconductor layers 13 on both sides of the ion implanted regions 14 can be connected together. The advantage of the vertically conductive semiconductor structure 2 is that the conduction current can be increased, and thereby power can be increased.

In addition to the above differences, for other structures and manufacturing methods of the vertically conductive semiconductor structure 2 in the second embodiment, reference can be made to the corresponding structures and process steps of the vertically conductive semiconductor structure 1 in the first embodiment.

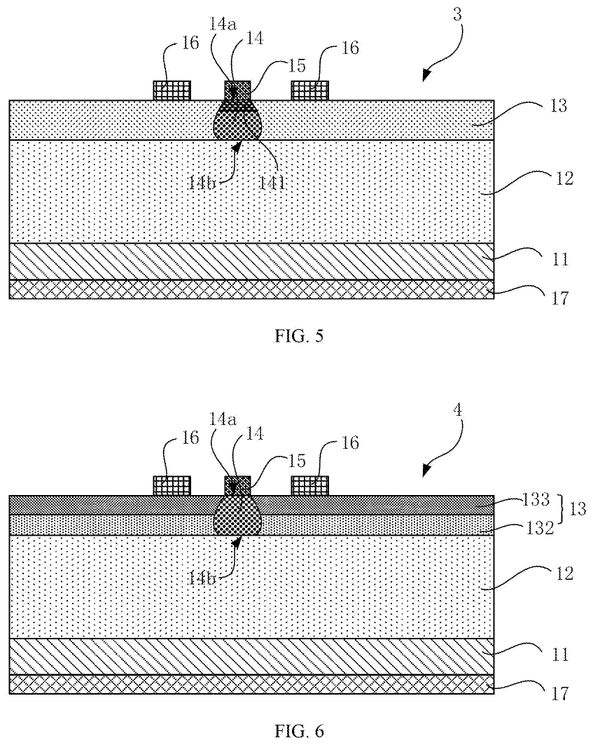

FIG. 5 is a cross-sectional diagram of a vertically conductive semiconductor structure according to the third embodiment of the present disclosure.

As shown in FIG. 5, a difference between a vertically conductive semiconductor structure 3 according to the third embodiment and the vertically conductive semiconductor structures 1 and 2 according to the first and second embodiments is only that the ion implanted region further includes a heavily doped region 141 in the ion implanted region 14 and far from the first semiconductor layer 12, where conductivity types of the heavily doped region 141 and the second semiconductor layer 13 are opposite.

The source electrode 15 connects the heavily doped region 141. The heavily doped region 141 can reduce the ohmic contact resistance between the source electrode 15 and the ion implanted region 14.

Correspondingly, the difference between the method for manufacturing the vertically conductive semiconductor structure 3 according to the third embodiment and the method for manufacturing the vertically conductive semiconductor structures 1 and 2 according to the first and second embodiments is only that after step S12 and before step S13, ions are implanted in a region of the ion implanted region 14 far from the first semiconductor layer 12 to form a heavily doped region 141. The conductivity types of the heavily doped region 141 and the second semiconductor layer 13 are opposite.

when the ions are implanted, the amount of the implantation for the heavily doped region 141 is greater than the amount of the implantation for the ion implanted region 14 except for the heavily doped region 141. The amount of the implantation for the heavily doped region 141 is, for example, greater than 1E19/cm3.

For example, unlike the ion implanted region 14 which is manufactured through high ion implantation energy and low ion implantation amount, the heavily doped region 141 is manufactured through low ion implantation energy and high ion implantation amount.

In addition to the above differences, for other steps of the method for manufacturing the vertically conductive semiconductor structure 3 in the third embodiment, reference can be made to the corresponding steps of the method for manufacturing the vertically conductive semiconductor structure 1 in the first embodiment.

FIG. 6 is a cross-sectional diagram of a vertically conductive semiconductor structure according to the fourth embodiment of the present disclosure.

As shown in FIG. 6, a difference between a vertically conductive semiconductor structure 4 according to the fourth embodiment and the vertically conductive semiconductor structures 1, 2, and 3 according to the first, second and third embodiments is only that the second semiconductor layer 13 includes a first doped layer 132 and a second doped layer 133 that are stacked, where the first doped layer 132 is close to the first semiconductor layer 12, and the second doped layer 133 is far from the first semiconductor layer 12, and a conductive-ion doping concentration of the first doped layer 132 is lower than a conductive-ion doping concentration of the second doped layer 133.

The low doping concentration of conductive ions in the first doped layer 132 can increase the breakdown voltage of the vertically conductive semiconductor structure 4.

In addition to the above differences, for other structures of the vertically conductive semiconductor structure 4 in the fourth embodiment, reference can be made to the corresponding structures of the vertically conductive semiconductor structures 1, 2 and 3 in the first, second and third embodiments.

Correspondingly, a difference between the manufacturing method of the vertically conductive semiconductor structure 4 in the fourth embodiment and the manufacturing methods of the vertically conductive semiconductor structures 1, 2, and 3 in the first, second and third embodiments is only that in step S11, in a step of forming the second semiconductor layer 13 by performing an in-situ doping epitaxial growth process on the substrate 10, doping with a first ion concentration is performed first, and then doping with a second ion concentration is performed, where the first ion concentration is smaller than the second ion concentration.

The doping concentration of the first doped layer 132 is relatively low, which can improve the quality of the epitaxial growth of the second doped layer 133 and reduce dislocations.

In other embodiments, in the epitaxial growth process, the ion doping concentration of the second semiconductor layer 13 can increase with process time. Correspondingly, in the grown second semiconductor layer 13, a region closer to the first semiconductor layer 12 has smaller doping concentration of conductive ions.

For example, in the epitaxial growth process, the ion doping concentration of the second semiconductor layer 13 can linearly increase, stepwise increase, or first remain constant and then increase with the process time. Correspondingly, in the grown second semiconductor layer 13, the conductive ion doping concentration increases linearly, stepwise increase, or first remain constant and then increase from bottom to top in the thickness direction of the second semiconductor layer 13.

In addition to the above differences, for other steps of the method for manufacturing the vertically conductive semiconductor structure 4 in the fourth embodiment, reference can be made to the corresponding steps of the method for manufacturing the vertically conductive semiconductor structures 1, 2 and 3 in the first, second and third embodiments.

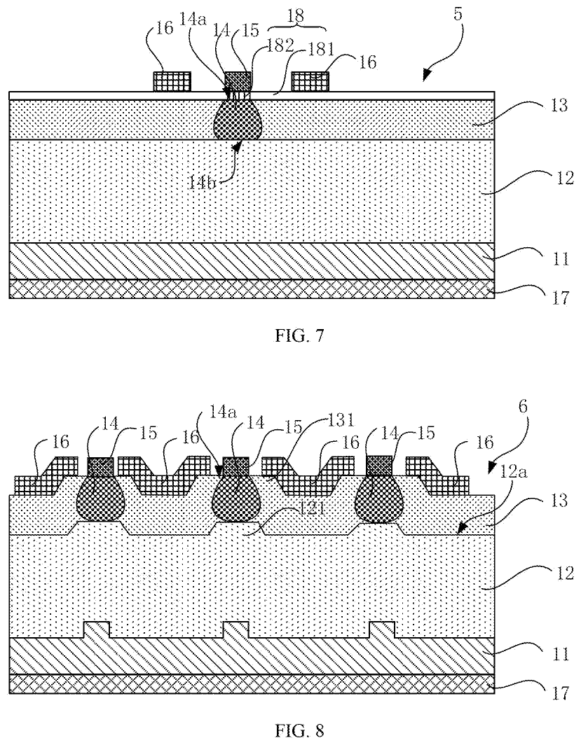

FIG. 7 is a cross-sectional diagram of a vertically conductive semiconductor structure according to the fifth embodiment of the present disclosure.

As shown in FIG. 7, a difference between a vertically conductive semiconductor structure 5 according to the fifth embodiment and the vertically conductive semiconductor structures 1, 2, 3, and 4 according to the first to fourth embodiments is that the ion implanted region 14 and the second semiconductor layer 13 are provided with a passivated layer 18. The passivated layer 18 includes a first section 181 corresponding to the second semiconductor layer 13 and a second section 182 corresponding to the ion implanted region 14, and the gate electrode 16 connects the first section 181, and the source electrode 15 connects the second segment 182.

A material of passivated layer 18 is a GAN-based material, such as AlGaN, where the Al content in AlGaN can increase from bottom to top in the thickness direction of the layer of AlGaN. The doping type of the first section 181 can be the same as the doping type of the second semiconductor layer 13, and the doping type of the second section 182 can be the same as the doping type of the ion implanted region 14.

Correspondingly, the difference between the method for manufacturing the vertically conductive semiconductor structure 5 according to the fifth embodiment and the method for manufacturing the vertically conductive semiconductor structures 1, 2, 3 and 4 according to the first to fourth embodiments is only that after step S12 and before step S13, a full surface passivated layer 18 is formed on the upper surfaces of the ion implanted region 14 and the second semiconductor layer 13, where the material of the passivated layer 18 can be AlGaN. On the one hand, the passivated layer 18 can reduce the leakage of current in the semiconductor structure to the electrode region. On the other hand, the passivated layer 18 can prevent ions in the lower material from migrating to the surface of the semiconductor structure to protect the upper structure, such as preventing the diffusion of Si and Mg atoms, to avoid impacts on the semiconductor structure.

When the material of the passivated layer 18 is AlGaN, the passivated layer 18 can be slightly doped with P-type ions, such as Mg ions; or slightly doped with N-type ions, such as Si ions; or without doping. In addition, the Al content in AlGaN can be fixed and ranges from 0 to 30% (including endpoint values). The Al content in AlGaN refers to the proportion of the amount of Al substance to the total amount of all cations. Alternatively, the Al content in AlGaN increases from bottom to top in the thickness direction of the AlGaN layer, where the Al content on the lower surface of the AlGaN layer in contact with the upper surfaces of the ion implanted region 14 and the second semiconductor layer 13 is 0, and the Al content on the upper surface of the AlGaN layer is 30%. The Al content of the passivated layer 18 gradually varies, which gradually increases the energy gap width of the passivated layer 18, increases the barrier height of a surface layer of the passivated layer 18, and significantly increases the reverse breakdown voltage.

After defects are repaired, the passivated layer 18 can be retained in the vertically conductive semiconductor structure 5.

FIG. 8 is a cross-sectional diagram of a vertically conductive semiconductor structure according to the sixth embodiment of the present disclosure.

As shown in FIG. 8, a difference between a vertically conductive semiconductor structure 6 according to the sixth embodiment and the vertically conductive semiconductor structures 1, 2, 3, 4, and 5 according to the first to fifth embodiments is that the first semiconductor layer 12 includes a first surface 12a facing away from the heavily doped layer 11, where the first surface 12a is provided with a plurality of first protrusions 121, and the ion implanted region 14 is formed above each of the plurality of the first protrusions 121; and a surface of the second semiconductor layer 13 facing away from the first semiconductor layer 12 is provided with a plurality of second protrusions 131 corresponding to the plurality of the first protrusions 121, and the ion implanted region 14 corresponding to each of the plurality of the second protrusions 131.

A part of the gate electrode 16 is formed in a groove between adjacent second protrusions 131.

In other embodiments, the surface of the second semiconductor layer 13 facing away from the first semiconductor layer 12 can also be flat. Compared to the formation of the gate electrode 16 on a plane, at least some part of the gate electrode 16 are formed in grooves, which can improve the control ability of gate 16 on the channel.

In addition to the above differences, for other structures of the vertically conductive semiconductor structure 6 in the sixth embodiment, reference can be made to the corresponding structures of the vertically conductive semiconductor structures 1, 2, 3, 4 and 5 in the first to fifth embodiments.

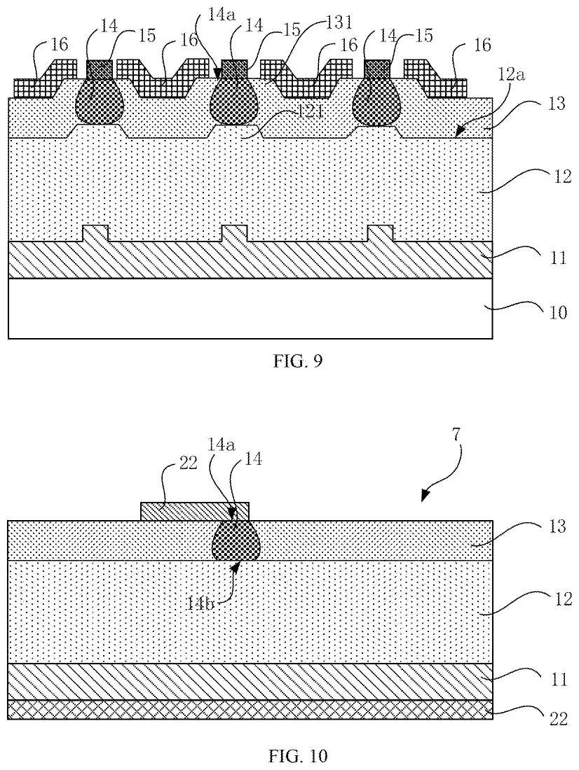

FIG. 9 is a schematic diagram of an intermediate structure corresponding to a method for manufacturing the vertically conductive semiconductor structure in the sixth embodiment of the present disclosure.

Correspondingly, the difference between the method for manufacturing the vertically conductive semiconductor structure 6 according to the sixth embodiment and the method for manufacturing the vertically conductive semiconductor structures 1, 2, 3, 4 and 5 according to the first to fifth embodiments is only that in step S11, referring to FIG. 9, the substrate 10 is a planar substrate, and the heavily doped layer 11 serves as a template with a patterned structure corresponding to the first protrusions 121. When the first semiconductor layer 12 and the second semiconductor layer 13 are epitaxially grown in step S12, the first semiconductor layer 12 forms the first protrusions 121, and the second semiconductor layer 13 forms the second protrusions 131.

In other embodiments, the substrate 10 can also be a patterned substrate, serving as a template with a patterned structure corresponding to the first protrusions 121. When the heavily doped layer 11, the first semiconductor layer 12, and the second semiconductor layer 13 are epitaxially grown in step S12, the heavily doped layer 11 forms a patterned structure corresponding to the patterned substrate, the first semiconductor layer 12 forms the first protrusions 121, and the second semiconductor layer 13 forms the second protrusions 131.

In addition to the above differences, for other steps of the method for manufacturing the vertically conductive semiconductor structure 6 in the sixth embodiment, reference can be made to the corresponding steps of the method for manufacturing the vertically conductive semiconductor structures 1, 2, 3, 4 and 5 in the first to fifth embodiments.

FIG. 10 is a cross-sectional diagram of a vertically conductive semiconductor structure according to the seventh embodiment of the present disclosure.

As shown in FIG. 10, a difference between a vertically conductive semiconductor structure 7 according to the seventh embodiment and the vertically conductive semiconductor structures 1, 2, 3, 4, and 5 according to the first to fifth embodiments is that the source electrode 15, drain electrode 17, and gate electrode 16 are omitted, and the first electrode 21 and second electrode 22 are provided. The first electrode 21 is connected to the first end 14a of the ion implanted region 14 and the second semiconductor layer 13 adjacent to the ion implanted region 14. The second electrode 22 is connected to the heavily doped layer 11. In other words, the vertically conductive semiconductor structure 7 is a diode.

Compared to the diode where the first electrode 21 is only connected to the ion implanted region 14, the first electrode 21 is simultaneously connected to the second semiconductor layer 13 adjacent to the ion implanted region 14, which can reduce the generation of electric field spikes and reduce leakage.

When the conductivity types of the heavily doped layer 11 and the first semiconductor layer 12 are N-type, and the conductivity type of the second semiconductor layer 13 is P-type, the channel of the diode is N-type, with the first electrode 21 being the anode and the second electrode 22 being the cathode. When the conductivity types of the heavily doped layer 11 and the first semiconductor layer 12 are P-type, and the conductivity type of the second semiconductor layer 13 is N-type, the channel of the diode is P-type, with the first electrode 21 being the cathode and the second electrode 22 being the anode.

When a heavily doped region 141 is provided in the ion implanted region 14, the first electrode 21 is connected to the second semiconductor layer 13 adjacent to the heavily doped region 141 and the ion implanted region 14.

Correspondingly, the difference between the method for manufacturing the vertically conductive semiconductor structure 7 according to the seventh embodiment and the method for manufacturing the vertically conductive semiconductor structures 1, 2, 3, 4 and 5 according to the first to fifth embodiments is only that step S13 is replaced by respectively forming the first electrode 21 and second electrode 22. The first electrode 21 is connected to the first end 14a of the ion implanted region 14 and the second semiconductor layer 13 adjacent to the ion implanted region 14. The second electrode 22 is connected to the heavily doped layer 11.

Compared with the prior art, the present disclosure has the following beneficial effects:

In some embodiments, by ion implantation, compared to a manufacturing process of filling semiconductor materials after etching grooves, defects can be reduced, carrier capture can be avoided, conduction current can be increased, and thereby power can be increased and conduction resistance can be reduced.

In some embodiments, since the width of the ion implanted region periodically varies, gradually increases or gradually decreases, a contact interface between the ion implanted region and a side of the second semiconductor layer has periodic changes or forms a tilted surface. On the one hand, by controlling a shape of a PN junction contact interface, a reverse breakdown voltage can be effectively increased. On the other hand, during on state, due to the periodically changed curved surface or tilted surface of the contact interface, electrons flowing from the source electrode to the drain electrode can disperse to both sides and flow downwards, which increases the electron movement path, thus further reducing the on-state resistance of the semiconductor structure.

In some embodiments, by controlling the variation of doped-ion concentration in the ion implanted region, the carrier concentration in the first semiconductor layer is locally modulated. The effect of local modulation for the doped ions in the ion implanted region is to effectively reduce the peak electric field intensity near the PN junction interface during off state, thereby maximizing the breakdown voltage of the device. During on state, this structure has a characteristic of reducing the conduction resistance, which allows the semiconductor structure to have a lower voltage drop under high current density when turned on, thus, improving the energy conversion efficiency of the system using this device.

In some embodiments, in the vertically conductive semiconductor structure and the manufacturing method therefor, the second semiconductor layer is formed on the first surface of the first semiconductor layer. Since first protrusions are formed on the first surface, second protrusions are formed on the side of the second semiconductor layer facing away from the first semiconductor layer. Compared to a method of forming second protrusions through etching, the second semiconductor layer is avoided from etching damage and the introduction of interface impurities.

Although the present disclosure is disclosed as above, the present disclosure is not limited thereto. Any person skilled in the art can make various changes and modifications without departing from the spirit and scope of the present disclosure, and therefore the scope of protection of the present disclosure shall be subject to the scope defined by the claims.

What is claimed is:

1. A vertically conductive semiconductor structure, comprising:
a heavily doped layer, a first semiconductor layer, and a second semiconductor layer that are arranged from bottom to top, wherein conductivity types of the heavily doped layer and the first semiconductor layer are same, and conductivity types of the first semiconductor layer and the second semiconductor layer are opposite, and materials of the first semiconductor layer and the second semiconductor layer are GaN-based materials; and
an ion implanted region in the second semiconductor layer, wherein conductivity types of the ion implanted region and the second semiconductor layer are opposite, the ion implanted region comprises a first end and a second end that are opposite to each other in a thickness direction, wherein the first end is flush with a surface of the second semiconductor layer far from the first semiconductor layer, and the second end connects the first semiconductor layer, and a width of the ion implanted region from bottom to top varies.

2. The structure according to claim 1, wherein from bottom to top, the width of the ion implanted region periodically varies, gradually increases, gradually decreases, first increases and then decreases, or first decreases and then increases.

3. The structure according to claim 1, further comprising a passivated layer on the surface of the second semiconductor layer far from the first semiconductor layer, wherein a material of the passivated layer is AlGaN, and a content of Al in the AlGaN increases from bottom to top in the thickness direction of the passivated layer.

4. The structure according to claim 1, wherein at least one of:
from bottom to top, a concentration of doped ions in the ion implanted region is unchanged,
from bottom to top, a concentration of doped ions in the ion implanted region periodically varies,
from bottom to top, a concentration of doped ions in the ion implanted region gradually increases, or
from bottom to top, a concentration of doped ions in the ion implanted region gradually decreases.

5. The structure according to claim 1, further comprising:
a source electrode connecting the first end of the ion implanted region;
a gate electrode at both sides of the source electrode, wherein the gate electrode connects the second semiconductor layer at both sides of the ion implanted region; and
a drain electrode connecting a surface of the heavily doped layer far from the first semiconductor layer.

6. The structure according to claim 1, further comprising:
a first electrode connecting the second semiconductor layer adjacent to the ion implanted region and the ion implanted region; and
a second electrode connecting the heavily doped layer.

7. The structure according to claim 1, wherein the ion implanted region further comprises a heavily doped region far from the first semiconductor layer, wherein conductivity types of the heavily doped region and the second semiconductor layer are opposite.

8. The structure according to claim 1, further comprising a buffer layer between the heavily doped layer and the first semiconductor layer.

9. The structure according to claim 1, wherein the first semiconductor layer comprises a first surface facing away from the heavily doped layer, wherein the first surface is provided with a plurality of first protrusions, and the ion implanted region is above each of the plurality of the first protrusions; and a surface of the second semiconductor layer facing away from the first semiconductor layer is provided with a plurality of second protrusions corresponding to the plurality of the first protrusions in position, or a surface of the second semiconductor layer facing away from the first semiconductor layer is flat.

10. The structure according to claim 1, wherein the second semiconductor layer comprises a first doped layer and a second doped layer that are stacked, wherein the first doped layer is close to the first semiconductor layer, and the second doped layer is far from the first semiconductor layer, and a conductive-ion doping concentration of the first doped layer is lower than a conductive-ion doping concentration of the second doped layer.

11. A method for manufacturing a vertically conductive semiconductor structure, comprising:
providing a heavily doped layer, a first semiconductor layer, and a second semiconductor layer that are arranged from bottom to top, wherein conductivity types of the heavily doped layer and the first semiconductor layer are same, and conductivity types of the first semiconductor layer and the second semiconductor layer are opposite, and materials of the first semiconductor layer and the second semiconductor layer are GaN-based materials; and
implanting ions in a region of a part of the second semiconductor layer to form an ion implanted region, wherein conductivity types of the ion implanted region and the second semiconductor layer are opposite, the ion implanted region connects the first semiconductor layer, and a width of the ion implanted region from bottom to top varies.

12. The method according to claim 11, wherein
before implanting the ions in the region of the part of the second semiconductor layer, the method further comprises: forming an in-situ protecting layer on a surface of the second semiconductor layer far from the first semiconductor layer; and
after implanting the ions in the region of the part of the second semiconductor layer, the method further comprises: performing first annealing, wherein a temperature of the first annealing is greater than 1100° C.; and removing the in-situ protecting layer and performing second annealing, wherein a temperature of the second annealing is less than 700° C.

13. The method according to claim 12, wherein the in-situ protecting layer is a single-layer structure, and a material of the single-layer structure comprises a mixture of at least one of SiN or AlN; or the in-situ protecting layer is a multi-layer structure, and the multi-layer structure from bottom to top comprises an SiN layer and an AlN layer, an AlN layer and an SiN layer, or an SiN layer, an AlN layer and an SiN layer.

14. The method according to claim 12, wherein the conductivity type of the second semiconductor layer is P-type, and H ions and at least one of Si ions, Ge ions, Sn ions, Se ions or Te ions are doped to form the ion implanted region with N-type conductivity.

15. The method according to claim 11, wherein the ion implanted region with varying widths and/or varying doping ion concentrations is obtained through multiple ion implantations.

16. The method according to claim 15, wherein
from bottom to top, the width of the ion implanted region periodically varies, gradually increases, gradually decreases, first increases and then decreases, or first decreases and then increases; and/or
from bottom to top, a concentration of doped ions in the ion implanted region at least one of: is unchanged, periodically varies, gradually increases, or gradually decreases; and/or
the multiple ion implantations comprise vertical implantation and oblique implantation; and/or
in the multiple ion implantations, energies of at least two ion implantations are different and/or amounts of at least two ion implantations are different.

17. The method according to claim 11, further comprising: implanting ions in a region of the ion implanted region far from the first semiconductor layer to form a heavily doped region, wherein conductivity types of the heavily doped region and the second semiconductor layer are opposite.

18. The method according to claim 11, wherein the first semiconductor layer and the second semiconductor layer are sequentially formed by performing epitaxial growth processes on a substrate, wherein the first semiconductor layer comprises a first surface facing away from the heavily doped layer, and the first surface is formed with a plurality of first protrusions; in the epitaxial growth processes, the ion implanted region is formed above the first protrusion; and a surface of the second semiconductor layer facing away from the first semiconductor layer is formed with a plurality of second protrusions corresponding to the plurality of the first protrusions in position, or a surface of the second semiconductor layer facing away from the first semiconductor layer is flat.

19. The method according to claim 18, wherein the substrate is a patterned substrate serving as a template and comprises a patterned structure corresponding to the plurality of the first protrusions; or the substrate is a planar substrate, and the heavily doped layer serves as a template and comprises a patterned structure corresponding to the plurality of the first protrusions.

20. The method according to claim 11, wherein after implanting the ions in the region of the part of the second semiconductor layer to form the ion implanted region, the method further comprises: forming a passivated layer on surfaces of the ion implanted region and the second semiconductor layer that are facing away from the first semiconductor layer, wherein a material of the passivated layer is AlGaN, and a content of Al in the AlGaN increases from bottom to top in a thickness direction of the passivated layer.
